(19) United States
(12) Patent Application Publication
(10) Pub. No.: US 2023/0203271 A1
(43) Pub. Date: Jun. 29, 2023

(54) EMI Shielding Polymer Composition

(71) Applicant: Ticona LLC, Florence, KY (US)

(72) Inventors: Yuehua Yu, Cincinnati, OH (US); Joseph Grenci, Florence, KY (US); Brian Hokkanen, Union, KY (US); Darin Grinsteinner, Fort Mitchel, KY (US); Jun Luo, Hicksville, NY (US); Prabuddha Bansal, Florence, KY (US)

(21) Appl. No.: 18/085,614

(22) Filed: Dec. 21, 2022

Related U.S. Application Data
(60) Provisional application No. 63/293,226, filed on Dec. 23, 2021.

(51) Int. Cl. C08K 3/04; C08K 9/04; H05K 9/00; G01S 13/931

(52) U.S. Cl. CPC C08K 3/04; C08K 9/04; G01S 13/931; H05K 9/0083; G01S 2013/9327

(57) ABSTRACT

A polymer composition containing a thermoplastic polymer and an electromagnetic interference filler is provided. At a thickness of 3.2 millimeters and over a frequency range from 2 GHz to 18 GHz, the composition may exhibit an average absorbency of about 25% or greater and an average electromagnetic interference shielding effectiveness of about 40 decibels or more, as determined in accordance with ASTM D4935-18.

### RELATED APPLICATION

The present application is based upon and claims priority to U.S. Provisional Pat. Application Serial No. 63/293,226, having a filing date of Dec. 23, 2021, which is incorporated herein by reference.

### BACKGROUND OF THE INVENTION

Radar modules are routinely employed in automotive vehicles (e.g., electric vehicles) to detect nearby objects. They can be used in short range applications such as blind spot detection, parking aid, and collision avoidance systems and in long range applications such as dynamic cruise control and cross traffic alert systems. Radar modules typically contain one or more printed circuit boards having electrical components dedicated to handling radio frequency (RF) radar signals, digital signal processing tasks, etc. To ensure that these components operate effectively, they are generally received in a housing structure and then covered with a radome that is transparent to radio waves. Because other surrounding electrical devices can generate electromagnetic interference (“EMI”) that can impact the accurate operation of the radar module, an EMI shield (e.g., aluminum plate) is generally positioned between the housing and printed circuit board. Additionally, as the radio signal transmitter antenna is typically positioned close to the radio signal receiver antenna, the transmitted waves can be reflected by components within the radar module toward the receiving antenna, causing interference. As such, there is a need for a material that can provide both EMI shielding properties as well as high levels of absorbency of radio waves in order to isolate the transmitting and receiving antennas and to clear the signal noise being reflected within the module. Additionally, as the automotive industry is continuing to require smaller and lighter components, there is a need for the material to be lightweight while maintaining good mechanical properties.

### SUMMARY OF THE INVENTION

In accordance with one embodiment of the present invention, a polymer composition is disclosed that includes an electromagnetic interference filler distributed within a polymer matrix that contains a thermoplastic polymer. At a thickness of 3.2 millimeters and over a frequency range from 2 GHz to 18 GHz, the composition exhibits an average absorbency of about 25% or greater and an average electromagnetic interference shielding effectiveness of about 40 decibels or more, as determined in accordance with ASTM D4935-18.

In accordance with another embodiment of the present invention, a radar module is disclosed that comprises a housing, at least one antenna element mounted in the housing, a shield mounted over a first side of the antenna element, and a radome mounted over the shield. The shield comprises a polymer composition that includes recycled carbon fibers distributed within a thermoplastic polymer matrix.

Other features and aspects of the present invention are set forth in greater detail below.

### BRIEF DESCRIPTION OF THE FIGURES

A full and enabling disclosure of the present invention, including the best mode thereof to one skilled in the art, is set forth more particularly in the remainder of the specification, including reference to the accompanying figures, in which:

FIG. 1 is a schematic exploded perspective view of a radar module in accordance with some embodiments of the present disclosure.

### DETAILED DESCRIPTION

It is to be understood by one of ordinary skill in the art that the present discussion is a description of exemplary embodiments only, and is not intended as limiting the broader aspects of the present invention.

Generally speaking, the present invention is directed to a polymer composition containing an EMI filler distributed within a polymer matrix containing a thermoplastic polymer. By selectively controlling the particular components of the composition and their relative concentration, the present inventors have discovered that the resulting composition may exhibit unique properties for use in a wide variety of possible product applications, such as electronic modules (e.g., radar modules) and other applications requiring radar absorbing materials. In certain embodiment, for example, the polymer composition may exhibit an EMI shielding effectiveness (“SE”) of about 40 decibels (dB) or more, in some embodiments about 45 dB or more, in some embodiments about 50 dB or more, and in some embodiments, from about 55 dB to about 100 dB, as determined in accordance with ASTM D4935-18 at a high frequency, such as 6 GHz. Notably, it has been discovered that the EMI shielding effectiveness may remain stable over a high frequency range, such as about 700 MHz or more, in some embodiments from about 1 GHz to about 100 GHz, in some embodiments from about 1 GHz to about 20 GHz, such as from about 1.5 GHz to about 10 GHz, and in some embodiments, from about 2 GHz to about 18 GHz. The EMI shielding effectiveness may also be within the desired range for a variety of different part thicknesses, such as from about 0.5 to about 10 millimeters, in some embodiments from about 0.8 to about 5 millimeters, and in some embodiments, from about 1 to about 4 millimeters (e.g., 1 millimeter, 1.6 millimeters, or 3.2 millimeters). Within these high frequency and/or thickness ranges, for example, the average EMI shielding effectiveness may be about 40 dB or more, in some embodiments about 45 dB or more, and in some embodiments, from about 50 dB to about 100 dB. Likewise, the minimum EMI shielding effectiveness may be about 10 dB or more, in some embodiments about 15 dB or more, and in some embodiments, from about 20 dB to about 100 dB. The composition may also have good EMI shielding effectiveness at lower frequencies, such as from 30 MHz to 1.5 GHz, such as from 200 MHz to 1.5 GHz. For example, within these lower frequency ranges and the thickness ranges noted above, the average EMI shielding effectiveness may be about 50 dB or more, in some embodiments about 55 dB or more, and in some embodiments, from about 60 dB to about 100 dB.

In addition to exhibiting good EMI shielding effectiveness, the composition may also exhibit high electronic wave absorbency within the same high frequency and/or thickness ranges as noted above. For example, the composition may have an average absorbency of about 25% or greater, in some embodiments about 30% or greater, and in some embodiments, from about 32% to about 40% at a frequency of 10 GHz. Additionally, over the range from 1 GHz to 20 GHz, such as from 2 GHz to 18 GHz, the composition has an absorbency of about 25% or greater, in some embodiments about 30% or greater, and in some embodiments, from about 32% to about 40% at thicknesses from about 1 to about 4 millimeters (e.g., 1 millimeter, 1.6 millimeters, or 3.2 millimeters). Further, in a frequency range from 30 MHz to 1.5 GHz, the composition can have an average absorbency of about 20% or greater, in some embodiments about 23% or greater, and in some embodiments, from about 25% to about 35% at thicknesses from about 1 to about 4 millimeters (e.g., 1 millimeter, 1.6 millimeters, or 3.2 millimeters). Furthermore, in a frequency range from 1.5 MHz to 10 GHz, the composition can have an average absorbency of about 20% or greater, in some embodiments about 25% or greater, and in some embodiments, from about 30% to about 40% at thicknesses from about 1 to about 4 millimeters (e.g., 1 millimeter, 1.6 millimeters, or 3.2 millimeters).

Conventionally, it was believed that polymer compositions exhibiting good EMI shielding effectiveness and absorbency would not also possess sufficient mechanical properties. It has been discovered, however, that the polymer composition is still able to maintain excellent mechanical properties. For example, the polymer composition may exhibit a Charpy notched impact strength of about 2 kJ/m² or more, in some embodiments from about 4 to about 20 kJ/m², and in some embodiments, from about 6 to about 10 kJ/m², measured at according to ISO Test No. 179-1:2010) (technically equivalent to ASTM D6110) at various temperatures, such as within a temperature range of from about -50° C. to about 85° C. (e.g., 23° C.). The tensile and flexural mechanical properties may also be good. For example, the polymer composition may exhibit a tensile strength of about 100 MPa or more, in some embodiments from about 150 MPa or more, and in some embodiments, from about 200 to about 300 MPa; a tensile break strain of about 0.1% or more, in some embodiments from about 0.5% to about 5%, and in some embodiments, from about 1.0% to about 2.5%; and/or a tensile modulus of from about 10,000 MPa to about 50,000 MPa, in some embodiments from about 20,000 MPa to about 40,000 MPa, and in some embodiments, from about 25,000 MPa to about 35,000 MPa. The tensile properties may be determined in accordance with ISO Test No. 527-1:2019 (technically equivalent to ASTM D638-14) at various temperatures, such as within a temperature range of from about -50° C. to about 85° C. (e.g., 23° C.). The polymer composition may also exhibit a flexural strength of from about 150 to about 600 MPa, in some embodiments from about 250 to about 500 MPa, and in some embodiments, from about 300 to about 400 MPa; a flexural break strain of about 0.5% or more, in some embodiments from about 0.8% to about 5%, and in some embodiments, from about 1.2% to about 2.5%; and/or a flexural modulus of from about 5,000 MPa to about 60,000 MPa, in some embodiments from about 20,000 MPa to about 55,000 MPa, and in some embodiments, from about 25,000 MPa to about 40,000 MPa. The flexural properties may be determined in accordance with ISO Test No. 178:2019 (technically equivalent to ASTM D790-17) at various temperatures, such as within a temperature range of from about -50° C. to about 85° C. (e.g., 23° C.).

The composition may also possess good thermal properties. For example, the polymer composition may exhibit a deflection temperature under load (DTUL) of about 150° C. or more, in some embodiments about 200° C. and in some embodiments, from about 250° C. to about 300° C., as determined in accordance with ISO 75-2:2013 (technically equivalent to ASTM D648-07) at a specified load of 1.8 MPa. The polymer composition can also be thermally conductive and thus, for example, exhibit an in-plane thermal conductivity of about 1 W/m-K or more, in some embodiments about 1.5 W/m-K or more, and in some embodiments, from about 2 to about 10 W/m-K, as determined in accordance with ASTM E 1461-13. The composition may also exhibit a through-plane thermal conductivity of about 0.3 W/m-K or more, in some embodiments about 0.4 W/m-K or more, in some embodiments about 0.5 W/m-K or more, and in some embodiments, from about 0.7 to about 3 W/m-K, as determined in accordance with ASTM E 1461-13.

Various embodiments of the present invention will now be described in more detail.

### I. Polymer Matrix

### A. Thermoplastic Polymers

As noted, the polymer matrix may contain one or more thermoplastic polymers. Typically, it is desired that such polymers have a high degree of heat resistance, such as reflected by a deflection temperature under load (“DTUL”) of about 40° C. or more, in some embodiments about 50° C. or more, in some embodiments about 60° C. or more, in some embodiments from about from about 80° C. to about 250° C., and in some embodiments, from about 100° C. to about 200° C., as determined in accordance with ISO 75-2:2013 at a load of 1.8 MPa. In addition to exhibiting a high degree of heat resistance, the thermoplastic polymers also typically have a high glass transition temperature, such as about 10° C. or more, in some embodiments about 20° C. or more, in some embodiments about 30° C. or more, in some embodiments about 40° C. or more, in some embodiments about 50° C. or more, and in some embodiments, from about 60° C. to about 320° C. When semi-crystalline or crystalline polymers are employed, the high performance polymers may also have a high melting temperature, such as about 140° C. or more, in some embodiments from about 150° C. to about 400° C., and in some embodiments, from about 200° C. to about 380° C. The glass transition and melting temperatures may be determined as is well known in the art using differential scanning calorimetry (“DSC”), such as determined by ISO 11357-2:2020 (glass transition) and 11357-3:2018 (melting).

Suitable thermoplastic polymers for this purpose may include, for instance, polyolefins (e.g., ethylene polymers, propylene polymers, etc.), polyamides (e.g., aliphatic, semi-aromatic, or aromatic polyamides), polyesters, polyarylene sulfides, liquid crystalline polymers (e.g., wholly aromatic polyesters, polyesteramides, etc.), polycarbonates, polyethers (e.g., polyoxymethylene), etc., as well as blends thereof. The exact choice of the polymer system will depend upon a variety of factors, such as the nature of other fillers included within the composition, the manner in which the composition is formed and/or processed, and the specific requirements of the intended application.

Aromatic polymers, for instance, may be suitable in some applications. The aromatic polymers can be substantially amorphous, semi-crystalline, or crystalline in nature. One example of a suitable semi-crystalline aromatic polymer, for instance, is an aromatic polyester, which may be a condensation product of at least one diol (e.g., aliphatic and/or cycloaliphatic) with at least one aromatic dicarboxylic acid, such as those having from 4 to 20 carbon atoms, and in some embodiments, from 8 to 14 carbon atoms. Suitable diols may include, for instance, neopentyl glycol, cyclohexanedimethanol, 2,2-dimethyl-1,3-propane diol and aliphatic glycols of the formula HO(CH₂)ₙOH where n is an integer of 2 to 10. Suitable aromatic dicarboxylic acids may include, for instance, isophthalic acid, terephthalic acid, 1,2-di(p-carboxyphenyl)ethane, 4,4′-dicarboxydiphenyl ether, etc., as well as combinations thereof. Fused rings can also be present such as in 1,4- or 1,5- or 2,6-naphthalene-dicarboxylic acids. Particular examples of such aromatic polyesters may include, for instance, polyethylene terephthalate) (PET), poly(1,4-butylene terephthalate) (PBT), poly(1,3-propylene terephthalate) (PPT), poly(1,4-butylene 2,6-naphthalate) (PBN), polyethylene 2,6-naphthalate) (PEN), poly(1,4-cyclohexylene dimethylene terephthalate) (PCT), as well as mixtures of the foregoing.

Derivatives and/or copolymers of aromatic polyesters (e.g., polyethylene terephthalate) may also be employed. For instance, in one embodiment, a modifying acid and/or diol may be used to form a derivative of such polymers. As used herein, the terms “modifying acid” and “modifying diol” are meant to define compounds that can form part of the acid and diol repeat units of a polyester, respectively, and which can modify a polyester to reduce its crystallinity or render the polyester amorphous. Examples of modifying acid components may include, but are not limited to, isophthalic acid, phthalic acid, 1,3-cyclohexanedicarboxylic acid, 1,4-cyclohexane dicarboxylic acid, 2,6-naphthaline dicarboxylic acid, succinic acid, glutaric acid, adipic acid, sebacic acid, suberic acid, 1,12-dodecanedioic acid, etc. In practice, it is often preferable to use a functional acid derivative thereof such as the dimethyl, diethyl, or dipropyl ester of the dicarboxylic acid. The anhydrides or acid halides of these acids also may be employed where practical. Examples of modifying diol components may include, but are not limited to, neopentyl glycol, 1,4-cyclohexanedimethanol, 1,2-propanediol, 1,3-propanediol, 2-methy-1,3-propanediol, 1,4-butanediol, 1,6-hexanediol, 1,2-cyclohexanediol, 1,4-cyclohexanediol, 1,2-cyclohexanedimethanol, 1,3-cyclohexanedimethanol, 2,2,4,4-tetramethyl 1,3-cyclobutane diol, Z,8-bis(hydroxymethyltricyclo-[5.2.1.0]-decane wherein Z represents 3, 4, or 5; 1,4-bis(2-hydroxyethoxy)benzene, 4,4′-bis(2-hydroxyethoxy) diphenylether [bis-hydroxyethyl bisphenol A], 4,4′-Bis(2-hydroxyethoxy)diphenylsulfide [bis-hydroxyethyl bisphenol S] and diols containing one or more oxygen atoms in the chain, e.g. diethylene glycol, triethylene glycol, dipropylene glycol, tripropylene glycol, etc. In general, these diols contain 2 to 18, and in some embodiments, 2 to 8 carbon atoms. Cycloaliphatic diols can be employed in their cis- or trans-configuration or as mixtures of both forms.

The aromatic polyesters, such as described above, typically have a DTUL value of from about 40° C. to about 80° C., in some embodiments from about 45° C. to about 75° C., and in some embodiments, from about 50° C. to about 70° C. as determined in accordance with ISO 75-2:2013 at a load of 1.8 MPa. The aromatic polyesters likewise typically have a glass transition temperature of from about 30° C. to about 120° C., in some embodiments from about 40° C. to about 110° C., and in some embodiments, from about 50° C. to about 100° C., such as determined by ISO 11357-2:2020, as well as a melting temperature of from about 170° C. to about 300° C., in some embodiments from about 190° C. to about 280° C., and in some embodiments, from about 210° C. to about 260° C., such as determined in accordance with ISO 11357-2:2018. The aromatic polyesters may also have an intrinsic viscosity of from about 0.1 dl/g to about 6 dl/g, in some embodiments from about 0.2 to about 5 dl/g, and in some embodiments from about 0.3 to about 1 dl/g, such as determined in accordance with ISO 1628-5:1998.

Polyarylene sulfides are also suitable semi-crystalline aromatic polymers. The polyarylene sulfide may be homopolymers or copolymers. For instance, selective combination of dihaloaromatic compounds can result in a polyarylene sulfide copolymer containing not less than two different units. For instance, when p-dichlorobenzene is used in combination with m-dichlorobenzene or 4,4′-dichlorodiphenylsulfone, a polyarylene sulfide copolymer can be formed containing segments having the structure of formula:

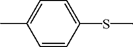

and segments having the structure of formula:

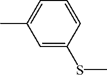

or segments having the structure of formula:

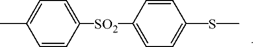

The polyarylene sulfide may be linear, semi-linear, branched or crosslinked. Linear polyarylene sulfides typically contain 80 mol% or more of the repeating unit -(Ar-S)-. Such linear polymers may also include a small amount of a branching unit or a cross-linking unit, but the amount of branching or cross-linking units is typically less than about 1 mol% of the total monomer units of the polyarylene sulfide. A linear polyarylene sulfide polymer may be a random copolymer or a block copolymer containing the above-mentioned repeating unit. Semi-linear polyarylene sulfides may likewise have a cross-linking structure or a branched structure introduced into the polymer a small amount of one or more monomers having three or more reactive functional groups. By way of example, monomer components used in forming a semi-linear polyarylene sulfide can include an amount of polyhaloaromatic compounds having two or more halogen substituents per molecule which can be utilized in preparing branched polymers. Such monomers can be represented by the formula R′Xₙ, where each X is selected from chlorine, bromine, and iodine, n is an integer of 3 to 6, and R′ is a polyvalent aromatic radical of valence n which can have up to about 4 methyl substituents, the total number of carbon atoms in R′ being within the range of 6 to about 16. Examples of some polyhaloaromatic compounds having more than two halogens substituted per molecule that can be employed in forming a semi-linear polyarylene sulfide include 1,2,3-trichlorobenzene, 1,2,4-trichlorobenzene, 1,3-dichloro-5-bromobenzene, 1,2,4-triiodobenzene, 1,2,3,5-tetrabromobenzene, hexachlorobenzene, 1,3,5-trichloro-2,4,6-trimethylbenzene, 2,2′,4,4′-tetrachlorobiphenyl, 2,2′,5,5′-tetra-iodobiphenyl, 2,2′,6,6′-tetrabromo-3,3′,5,5′-tetramethylbiphenyl, 1,2,3,4-tetrachloronaphthalene, 1,2,4-tribromo-6-methylnaphthalene, etc., and mixtures thereof.

The polyarylene sulfides, such as described above, typically have a DTUL value of from about 70° C. to about 220° C., in some embodiments from about 90° C. to about 200° C., and in some embodiments, from about 120° C. to about 180° C. as determined in accordance with ISO 75-2:2013 at a load of 1.8 MPa. The polyarylene sulfides likewise typically have a glass transition temperature of from about 50° C. to about 120° C., in some embodiments from about 60° C. to about 115° C., and in some embodiments, from about 70° C. to about 110° C., such as determined by ISO 11357-2:2020, as well as a melting temperature of from about 220° C. to about 340° C., in some embodiments from about 240° C. to about 320° C., and in some embodiments, from about 260° C. to about 300° C., such as determined in accordance with ISO 11357-3:2018.

As indicated above, substantially amorphous polymers may also be employed that lack a distinct melting point temperature. Suitable amorphous polymers may include, for instance, aromatic polycarbonates, which typically contains repeating structural carbonate units of the formula -R¹-O-C(O)-O-. The polycarbonate is aromatic in that at least a portion (e.g., 60% or more) of the total number of R¹ groups contain aromatic moieties and the balance thereof are aliphatic, alicyclic, or aromatic. In one embodiment, for instance, R¹ may a C₆₋₃₀ aromatic group, that is, contains at least one aromatic moiety. Typically, R¹ is derived from a dihydroxy aromatic compound of the general formula HO-R¹-OH, such as those having the specific formula referenced below:

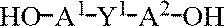

wherein,
A¹ and A² are independently a monocyclic divalent aromatic group; and
Y¹ is a single bond or a bridging group having one or more atoms that separate A¹ from A². In one particular embodiment, the dihydroxy aromatic compound may be derived from the following formula (I):

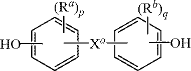

wherein,
R^{a} and R^{b} are each independently a halogen or C₁₋₁₂ alkyl group, such as a C₁₋₃ alkyl group (e.g., methyl) disposed meta to the hydroxy group on each arylene group;
p and q are each independently 0 to 4 (e.g., 1); and
X^{a} represents a bridging group connecting the two hydroxy-substituted aromatic groups, where the bridging group and the hydroxy substituent of each C₆ arylene group are disposed ortho, meta, or para (specifically para) to each other on the C₆ arylene group.

In one embodiment, X^{a} may be a substituted or unsubstituted C₃₋₁₈ cycloalkylidene, a C₁₋₂₅ alkylidene of formula -C(R^{c})(R^{d})- wherein R^{c} and R^{d} are each independently hydrogen, C₁₋₁₂ alkyl, C₁₋₁₂ cycloalkyl, C₇₋₁₂ arylalcyl, C₇₋₁₂ heteroalkyl, or cyclic C₇₋₁₂ heteroarylalkyl, or a group of the formula -C(=R^{e})-wherein R^{e} is a divalent C₁₋₁₂ hydrocarbon group. Exemplary groups of this type include methylene, cyclohexylmethylene, ethylidene, neopentylidene, and isopropylidene, as well as 2-[2.2.1]-bicycloheptylidene, cyclohexylidene, cyclopentylidene, cyclododecylidene, and adamantylidene. A specific example wherein X^{a} is a substituted cycloalkylidene is the cyclohexylidene-bridged, alkylsubstituted bisphenol of the following formula (II):

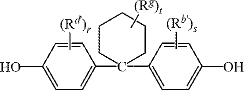

wherein,
R^{a′} and R^{b′} are each independently C₁₋₁₂ alkyl (e.g., C₁₋₄ alkyl, such as methyl), and may optionally be disposed meta to the cyclohexylidene bridging group;
R^{g} is C₁₋₁₂ alkyl (e.g., C₁₋₄ alkyl) or halogen;
r and s are each independently 1 to 4 (e.g., 1); and
t is 0 to 10, such as 0 to 5.

The cyclohexylidene-bridged bisphenol can be the reaction product of two moles of o-cresol with one mole of cyclohexanone. In another embodiment, the cyclohexylidene-bridged bisphenol can be the reaction product of two moles of a cresol with one mole of a hydrogenated isophorone (e.g., 1,1,3-trimethyl-3-cyclohexane-5-one). Such cyclohexane-containing bisphenols, for example the reaction product of two moles of a phenol with one mole of a hydrogenated isophorone, are useful for making polycarbonate polymers with high glass transition temperatures and high heat distortion temperatures.

In another embodiment, X^{a} may be a C₁₋₁₈ alkylene group, a C₃₋₁₈ cycloalkylene group, a fused C₆₋₁₈ cycloalkylene group, or a group of the formula -B¹-W-B²-, wherein B¹ and B² are independently a C₁₋₆ alkylene group and W is a C₃₋₁₂ cycloalkylidene group or a C₆₋₁₆ arylene group.

X^{a} may also be a substituted C₃₋₁₈ cycloalkylidene of the following formula (III):

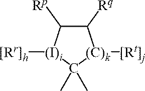

wherein,
R^{r}, R^{p}, R^{q}, and R^{t} are each independently hydrogen, halogen, oxygen, or C₁₋₁₂ organic groups;
I is a direct bond, a carbon, or a divalent oxygen, sulfur, or -N(Z)-, wherein Z is hydrogen, halogen, hydroxy, C₁₋₁₂ alkyl, C₁₋₁₂ alkoxy, or C₁₋₁₂ acyl;
h is 0 to 2;
j is 1 or 2;
i is 0 or 1; and
k is 0 to 3, with the proviso that at least two of R^{r}, R^{p}, R^{q}, and R^{t} taken together are a fused cycloaliphatic, aromatic, or heteroaromatic ring.

Other useful aromatic dihydroxy aromatic compounds include those having the following formula (IV):

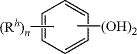

wherein,
R^{h} is independently a halogen atom (e.g., bromine), C₁₋₁₀ hydrocarbyl (e.g., C₁₋₁₀ alkyl group), a halogen-substituted C₁₋₁₀ alkyl group, a C₆₋₁₀ aryl group, or a halogen-substituted C₆₋₁₀ aryl group;
n is 0 to 4.

Specific examples of bisphenol compounds of formula (I) include, for instance, 1,1-bis(4-hydroxyphenyl) methane, 1,1-bis(4-hydroxyphenyl) ethane, 2,2-bis(4-hydroxyphenyl)propane (hereinafter “bisphenol A” or “BPA”), 2,2-bis(4-hydroxyphenyl)butane, 2,2-bis(4-hydroxyphenyl)octane, 1,1-bis(4-hydroxyphenyl)propane, 1,1-bis(4-hydroxyphenyl) n-butane, 2,2-bis(4-hydroxy-1-methylphenyl)propane, 1,1-bis(4-hydroxy-t-butylphenyl)propane, 3,3-bis(4-hydroxyphenyl)phthalimidine, 2-phenyl-3,3-bis(4-hydroxyphenyl)phthalimidine (PPPBP), and 1,1-bis(4-hydroxy-3-methylphenyl)cyclohexane (DMBPC). In one specific embodiment, the polycarbonate may be a linear homopolymer derived from bisphenol A, in which each of A¹ and A² is p-phenylene and Y¹ is isopropylidene in formula (I).

Other examples of suitable aromatic dihydroxy compounds may include, but not limited to, 4,4′-dihydroxybiphenyl, 1,6-dihydroxynaphthalene, 2,6-dihydroxynaphthalene, bis(4-hydroxyphenyl)methane, bis(4-hydroxyphenyl)diphenylmethane, bis(4-hydroxyphenyl)-1-naphthylmethane, 1,2-bis(4-hydroxyphenyl)ethane, 1,1-bis(4-hydroxyphenyl)-1-phenylethane, 2-(4-hydroxyphenyl)-2-(3-hydroxyphenyl)propane, bis(4-hydroxyphenyl)phenylmethane, 2,2-bis(4-hydroxy-3-bromophenyl)propane, 1,1-bis (hydroxyphenyl)cyclopentane, 1,1-bis(4-hydroxyphenyl)cyclohexane, 1,1-bis(4-hydroxyphenyl)isobutene, 1,1-bis(4-hydroxyphenyl)cyclododecane, trans-2,3-bis(4-hydroxyphenyl)-2-butene, 2,2-bis(4-hydroxyphenyl)adamantane, alpha, alpha′-bis(4-hydroxyphenyl)toluene, bis(4-hydroxyphenyl)acetonitrile, 2,2-bis(3-methyl-4-hydroxyphenyl)propane, 2,2-bis(3-ethyl-4-hydroxyphenyl)propane, 2,2-bis(3-n-propyl-4-hydroxyphenyl)propane, 2,2-bis(3-isopropyl-4-hydroxyphenyl)propane, 2,2-bis(3-sec-butyl-4-hydroxyphenyl)propane, 2,2-bis(3-t-butyl-4-hydroxyphenyl)propane, 2,2-bis(3-cyclohexyl-4-hydroxyphenyl)propane, 2,2-bis(3-allyl-4-hydroxyphenyl)propane, 2,2-bis(3-methoxy-4-hydroxyphenyl)propane, 2,2-bis(4-hydroxyphenyl)hexafluoropropane, 1,1-dichloro-2,2-bis(4-hydroxyphenyl)ethylene, 1,1-dibromo-2,2-bis(4-hydroxyphenyl)ethylene, 1,1-dichloro-2,2-bis(5-phenoxy-4-hydroxyphenyl)ethylene 4,4′-dihydroxybenzophenone, 3,3-bis(4-hydroxyphenyl)-2-butanone, 1,6-bis(4-hydroxyphenyl)-1,6-hexanedione, ethylene glycol bis(4-hydroxyphenyl)ether, bis(4-hydroxyphenyl)ether, bis(4-hydroxyphenyl)sulfide, bis(4-hydroxyphenyl)sulfoxide, bis(4-hydroxyphenyl)sulfone, 9,9-bis(4-hydroxyphenyl)fluorine, 2,7-dihydroxypyrene, 6,6′-dihydroxy-3,3,3′,3′-tetramethylspiro(bis)indane (“spirobiindane bisphenol”), 3,3-bis(4-hydroxyphenyl)phthalimide, 2,6-dihydroxydibenzo-p-dioxin, 2,6-dihydroxythianthrene, 2,7-dihydroxyphenoxathin, 2,7-dihydroxy-9,10-dimethylphenazine, 3,6-dihydroxydibenzofuran, 3,6-dihydroxydibenzothiophene, and 2,7-dihydroxycarbazole, resorcinol, substituted resorcinol compounds such as 5-methyl resorcinol, 5-ethyl resorcinol, 5-propyl resorcinol, 5-butyl resorcinol, 5-t-butyl resorcinol, 5-phenyl resorcinol, 5-cumyl resorcinol, 2,4,5,6-tetrafluoro resorcinol, 2,4,5,6-tetrabromo resorcinol, or the like; catechol; hydroquinone; substituted hydroquinones such as 2-methyl hydroquinone, 2-ethyl hydroquinone, 2-propyl hydroquinone, 2-butyl hydroquinone, 2-t-butyl hydroquinone, 2-phenyl hydroquinone, 2-cumyl hydroquinone, 2,3,5,6-tetramethyl hydroquinone, 2,3,5,6-tetra-t-butyl hydroquinone, 2,3,5,6-tetrafluoro hydroquinone, 2,3,5,6-tetrabromo hydroquinone, etc., as well as combinations thereof.

Aromatic polycarbonates, such as described above, typically have a DTUL value of from about 80° C. to about 300° C., in some embodiments from about 100° C. to about 250° C., and in some embodiments, from about 140° C. to about 220° C., as determined in accordance with ISO 75-2:2013 at a load of 1.8 MPa. The glass transition temperature may also be from about 50° C. to about 250° C., in some embodiments from about 90° C. to about 220° C., and in some embodiments, from about 100° C. to about 200° C., such as determined by ISO 11357-2:2020. Such polycarbonates may also have an intrinsic viscosity of from about 0.1 dl/g to about 6 dl/g, in some embodiments from about 0.2 to about 5 dl/g, and in some embodiments from about 0.3 to about 1 dl/g, such as determined in accordance with ISO 1628-4:1998.

In addition to the polymers referenced above, highly crystalline aromatic polymers may also be employed in the polymer composition. Particularly suitable examples of such polymers are liquid crystalline polymers, which have a high degree of crystallinity that enables them to effectively fill the small spaces of a mold. Liquid crystalline polymers are generally classified as “thermotropic” to the extent that they can possess a rod-like structure and exhibit a crystalline behavior in their molten state (e.g., thermotropic nematic state). Such polymer typically have a DTUL value of from about 120° C. to about 340° C., in some embodiments from about 140° C. to about 320° C., and in some embodiments, from about 150° C. to about 300° C., as determined in accordance with ISO 75-2:2013 at a load of 1.8 MPa. The polymers also have a relatively high melting temperature, such as from about 250° C. to about 400° C., in some embodiments from about 280° C. to about 390° C., and in some embodiments, from about 300° C. to about 380° C. Such polymers may be formed from one or more types of repeating units as is known in the art.

A liquid crystalline polymer may, for example, contain one or more aromatic ester repeating units, typically in an amount of from about 60 mol.% to about 99.9 mol.%, in some embodiments from about 70 mol.% to about 99.5 mol.%, and in some embodiments, from about 80 mol.% to about 99 mol.% of the polymer. The aromatic ester repeating units may be generally represented by the following Formula (V):

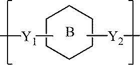

wherein,
ring B is a substituted or unsubstituted 6-membered aryl group (e.g., 1,4-phenylene or 1,3-phenylene), a substituted or unsubstituted 6-membered aryl group fused to a substituted or unsubstituted 5- or 6-membered aryl group (e.g., 2,6-naphthalene), or a substituted or unsubstituted 6-membered aryl group linked to a substituted or unsubstituted 5- or 6-membered aryl group (e.g., 4,4-biphenylene); and
Y₁ and Y₂ are independently O, C(O), NH, C(O)HN, or NHC(O).

Typically, at least one of Y₁ and Y₂ are C(O). Examples of such aromatic ester repeating units may include, for instance, aromatic dicarboxylic repeating units (Y₁ and Y₂ in Formula V are C(O)), aromatic hydroxycarboxylic repeating units (Y₁ is O and Y₂ is C(O) in Formula V), as well as various combinations thereof.

Aromatic dicarboxylic repeating units, for instance, may be employed that are derived from aromatic dicarboxylic acids, such as terephthalic acid, isophthalic acid, 2,6-naphthalenedicarboxylic acid, diphenyl ether-4,4′-dicarboxylic acid, 1,6-naphthalenedicarboxylic acid, 2,7-naphthalenedicarboxylic acid, 4,4′-dicarboxybiphenyl, bis(4-carboxyphenyl)ether, bis(4-carboxyphenyl)butane, bis(4-carboxyphenyl)ethane, bis(3-carboxyphenyl)ether, bis(3-carboxyphenyl)ethane, etc., as well as alkyl, alkoxy, aryl and halogen substituents thereof, and combinations thereof. Particularly suitable aromatic dicarboxylic acids may include, for instance, terephthalic acid (“TA”), isophthalic acid (“IA”), and 2,6-naphthalenedicarboxylic acid (“NDA”). When employed, repeating units derived from aromatic dicarboxylic acids (e.g., IA, TA, and/or NDA) typically constitute from about 5 mol.% to about 60 mol.%, in some embodiments from about 10 mol.% to about 55 mol.%, and in some embodiments, from about 15 mol.% to about 50% of the polymer.

Aromatic hydroxycarboxylic repeating units may also be employed that are derived from aromatic hydroxycarboxylic acids, such as, 4-hydroxybenzoic acid; 4-hydroxy-4′-biphenylcarboxylic acid; 2-hydroxy-6-naphthoic acid; 2-hydroxy-5-naphthoic acid; 3-hydroxy-2-naphthoic acid; 2-hydroxy-3-naphthoic acid; 4′-hydroxyphenyl-4-benzoic acid; 3′-hydroxyphenyl-4-benzoic acid; 4′-hydroxyphenyl-3-benzoic acid, etc., as well as alkyl, alkoxy, aryl and halogen substituents thereof, and combination thereof. Particularly suitable aromatic hydroxycarboxylic acids are 4-hydroxybenzoic acid (“HBA”) and 6-hydroxy-2-naphthoic acid (“HNA”). When employed, repeating units derived from hydroxycarboxylic acids (e.g., HBA and/or HNA) typically constitute from about 10 mol.% to about 85 mol.%, in some embodiments from about 20 mol.% to about 80 mol.%, and in some embodiments, from about 25 mol.% to about 75% of the polymer.

Other repeating units may also be employed in the polymer. In certain embodiments, for instance, repeating units may be employed that are derived from aromatic diols, such as hydroquinone, resorcinol, 2,6-dihydroxynaphthalene, 2,7-dihydroxynaphthalene, 1,6-dihydroxynaphthalene, 4,4′-dihydroxybiphenyl (or 4,4′-biphenol), 3,3′-dihydroxybiphenyl, 3,4′-dihydroxybiphenyl, 4,4′-dihydroxybiphenyl ether, bis(4-hydroxyphenyl)ethane, etc., as well as alkyl, alkoxy, aryl and halogen substituents thereof, and combinations thereof. Particularly suitable aromatic diols may include, for instance, hydroquinone (“HQ”) and 4,4′-biphenol (“BP”). When employed, repeating units derived from aromatic diols (e.g., HQ and/or BP) typically constitute from about 1 mol.% to about 30 mol.%, in some embodiments from about 2 mol.% to about 25 mol.%, and in some embodiments, from about 5 mol.% to about 20% of the polymer. Repeating units may also be employed, such as those derived from aromatic amides (e.g., acetaminophen (“APAP”)) and/or aromatic amines (e.g., 4-aminophenol (“AP”), 3-aminophenol, 1,4-phenylenediamine, 1,3-phenylenediamine, etc.). When employed, repeating units derived from aromatic amides (e.g., APAP) and/or aromatic amines (e.g., AP) typically constitute from about 0.1 mol.% to about 20 mol.%, in some embodiments from about 0.5 mol.% to about 15 mol.%, and in some embodiments, from about 1 mol.% to about 10% of the polymer. It should also be understood that various other monomeric repeating units may be incorporated into the polymer. For instance, in certain embodiments, the polymer may contain one or more repeating units derived from non-aromatic monomers, such as aliphatic or cycloaliphatic hydroxycarboxylic acids, dicarboxylic acids, diols, amides, amines, etc. Of course, in other embodiments, the polymer may be “wholly aromatic” in that it lacks repeating units derived from non-aromatic (e.g., aliphatic or cycloaliphatic) monomers.

In one particular embodiment, the liquid crystalline polymer may be formed from repeating units derived from 4-hydroxybenzoic acid (“HBA”) and terephthalic acid (“TA”) and/or isophthalic acid (“IA”), as well as various other optional constituents. The repeating units derived from 4-hydroxybenzoic acid (“HBA”) may constitute from about 10 mol.% to about 80 mol.%, in some embodiments from about 30 mol.% to about 75 mol.%, and in some embodiments, from about 45 mol.% to about 70% of the polymer. The repeating units derived from terephthalic acid (“TA”) and/or isophthalic acid (“IA”) may likewise constitute from about 5 mol.% to about 40 mol.%, in some embodiments from about 10 mol.% to about 35 mol.%, and in some embodiments, from about 15 mol.% to about 35% of the polymer. Repeating units may also be employed that are derived from 4,4′-biphenol (“BP”) and/or hydroquinone (“HQ”) in an amount from about 1 mol.% to about 30 mol.%, in some embodiments from about 2 mol.% to about 25 mol.%, and in some embodiments, from about 5 mol.% to about 20% of the polymer. Other possible repeating units may include those derived from 6-hydroxy-2-naphthoic acid (“HNA”), 2,6-naphthalenedicarboxylic acid (“NDA”), and/or acetaminophen (“APAP”). In certain embodiments, for example, repeating units derived from HNA, NDA, and/or APAP may each constitute from about 1 mol.% to about 35 mol.%, in some embodiments from about 2 mol.% to about 30 mol.%, and in some embodiments, from about 3 mol.% to about 25 mol.% when employed.

Of course, besides aromatic polymers, aliphatic polymers may also be suitable for use as high performance, thermoplastic polymers in the polymer matrix. In one embodiment, for instance, polyamides may be employed that generally have a CO-NH linkage in the main chain and are obtained by condensation of an aliphatic diamine and an aliphatic dicarboxylic acid, by ring opening polymerization of lactam, or self-condensation of an amino carboxylic acid. For example, the polyamide may contain aliphatic repeating units derived from an aliphatic diamine, which typically has from 4 to 14 carbon atoms. Examples of such diamines include linear aliphatic alkylenediamines, such as 1,4-tetramethylenediamine, 1,6-hexanediamine, 1,7-heptanediamine, 1,8-octanediamine, 1,9-nonanediamine, 1,10-decanediamine, 1,11-undecanediamine, 1,12-dodecanediamine, etc.; branched aliphatic alkylenediamines, such as 2-methyl-1,5-pentanediamine, 3-methyl-1,5 pentanediamine, 2,2,4-trimethyl-1,6-hexanediamine, 2,4,4-trimethyl-1,6-hexanediamine, 2,4-dimethyl-1,6-hexanediamine, 2-methyl-1,8-octanediamine, 5-methyl-1,9-nonanediamine, etc.; as well as combinations thereof. Aliphatic dicarboxylic acids may include, for instance, adipic acid, sebacic acid, etc. Particular examples of such aliphatic polyamides include, for instance, nylon-4 (poly-a-pyrrolidone), nylon-6 (polycaproamide), nylon-11 (polyundecanamide), nylon-12 (polydodecanamide), nylon-46 (polytetramethylene adipamide), nylon-66 (polyhexamethylene adipamide), nylon-610, and nylon-612. Nylon-6 and nylon-66 are particularly suitable.

It should be understood that it is also possible to include aromatic monomer units in the polyamide such that it is considered aromatic (contains only aromatic monomer units are both aliphatic and aromatic monomer units). Examples of aromatic dicarboxylic acids may include, for instance, terephthalic acid, isophthalic acid, 2,6-naphthalenedicarboxylic acid, 2,7-naphthalenedicarboxylic acid, 1,4-naphthalenedicarboxylic acid, 1,4-phenylenedioxy-diacetic acid, 1,3-phenylenedioxy-diacetic acid, diphenic acid, 4,4′-oxydibenzoic acid, diphenylmethane-4,4′-dicarboxylic acid, diphenylsulfone-4,4′-dicarboxylic acid, 4,4′-biphenyldicarboxylic acid, etc. Particularly suitable aromatic polyamides may include poly(nonamethylene terephthalamide) (PA9T), poly(nonamethylene terephthalamide/nonamethylene decanediamide) (PA9T/910), poly(nonamethylene terephthalamide/nonamethylene dodecanediamide) (PA9T/912), poly(nonamethylene terephthalamide/11-aminoundecanamide) (PA9T/11), poly(nonamethylene terephthalamide/12-aminododecanamide) (PA9T/12), poly(decamethylene terephthalamide/11-aminoundecanamide) (PA10T/11), poly(decamethylene terephthalamide/12-aminododecanamide) (PA10T/12), poly(decamethylene terephthalamide/decamethylene decanediamide) (PA10T/1010), poly(decamethylene terephthalamide/decamethylene dodecanediamide) (PA10T/1012), poly(decamethylene terephlhalamide/tetramethylene hexanediamide) (PA10T/46), poly(decamethylene terephthalamide/caprolactam) (PA10T/6), poly(decamethylene terephthalamide/hexamethylene hexanediamide) (PA10T/66), poly(dodecamethylene lerephthalamide/dodecamelhylene dodecanediarnide) (PA12T/1212), poly(dodecamethylene terephthalamide/caprolactam) (PA12T/6), poly(dodecamethylene terephthalamide/hexamethylene hexanediamide) (PA12T/66), and so forth.

Suitable polyamides for the polymer matrix are typically crystalline or semi-crystalline in nature and thus has a measurable melting temperature. The melting temperature may be relatively high such that the composition can provide a substantial degree of heat resistance to a resulting part. For example, the polyamide may have a melting temperature of about 220° C. or more, in some embodiments from about 240° C. to about 325° C., and in some embodiments, from about 250° C. to about 335° C. The polyamide may also have a relatively high glass transition temperature, such as about 30° C. or more, in some embodiments about 40° C. or more, and in some embodiments, from about 45° C. to about 140° C. The glass transition and melting temperatures may be determined as is well known in the art using differential scanning calorimetry (“DSC”), such as determined by ISO Test No. 11357-2:2020 (glass transition) and 11357-3:2018 (melting).

Propylene polymers may also be suitable aliphatic high performance polymers for use in the polymer matrix. Any of a variety of propylene polymers or combinations of propylene polymers may generally be employed in the polymer matrix, such as propylene homopolymers (e.g., syndiotactic, atactic, isotactic, etc.), propylene copolymers, and so forth. In one embodiment, for instance, a propylene polymer may be employed that is an isotactic or syndiotactic homopolymer. The term “syndiotactic” generally refers to a tacticity in which a substantial portion, if not all, of the methyl groups alternate on opposite sides along the polymer chain. On the other hand, the term “isotactic” generally refers to a tacticity in which a substantial portion, if not all, of the methyl groups are on the same side along the polymer chain. In yet other embodiments, a copolymer of propylene with an α-olefin monomer may be employed. Specific examples of suitable α-olefin monomers may include ethylene, 1-butene; 3-methyl-1-butene; 3,3-dimethyl-1-butene; 1-pentene; 1-pentene with one or more methyl, ethyl or propyl substituents; 1-hexene with one or more methyl, ethyl or propyl substituents; 1-heptene with one or more methyl, ethyl or propyl substituents; 1-octene with one or more methyl, ethyl or propyl substituents; 1-nonene with one or more methyl, ethyl or propyl substituents; ethyl, methyl or dimethyl-substituted 1-decene; 1-dodecene; and styrene. The propylene content of such copolymers may be from about 60 mol.% to about 99 mol.%, in some embodiments from about 80 mol.% to about 98.5 mol.%, and in some embodiments, from about 87 mol.% to about 97.5 mol.%. The α-olefin content may likewise range from about 1 mol.% to about 40 mol.%, in some embodiments from about 1.5 mol.% to about 15 mol.%, and in some embodiments, from about 2.5 mol.% to about 13 mol.%.

Suitable propylene polymers are typically those having a DTUL value of from about 80° C. to about 250° C., in some embodiments from about 100° C. to about 220° C., and in some embodiments, from about 110° C. to about 200° C., as determined in accordance with ISO 75-2:2013 at a load of 1.8 MPa. The glass transition temperature of such polymers may likewise be from about 10° C. to about 80° C., in some embodiments from about 15° C. to about 70° C., and in some embodiments, from about 20° C. to about 60° C., such as determined by ISO 11357-2:2020. Further, the melting temperature of such polymers may be from about 50° C. to about 250° C., in some embodiments from about 90° C. to about 220° C., and in some embodiments, from about 100° C. to about 200° C., such as determined by ISO 11357-3:2018.

Oxymethylene polymers may also be suitable aliphatic high performance polymers for use in the polymer matrix. Oxymethylene polymers can be either one or more homopolymers, copolymers, or a mixture thereof. Homopolymers are prepared by polymerizing formaldehyde or formaldehyde equivalents, such as cyclic oligomers of formaldehyde. Copolymers can contain one or more comonomers generally used in preparing polyoxymethylene compositions. Commonly used comonomers include alkylene oxides of 2-12 carbon atoms. If a copolymer is selected, the quantity of comonomer will typically not be more than 20 weight percent, in some embodiments not more than 15 weight percent, and, in some embodiments, about two weight percent. Comonomers can include ethylene oxide and butylene oxide. It is preferred that the homo- and copolymers are: 1) those whose terminal hydroxy groups are end-capped by a chemical reaction to form ester or ether groups; or, 2) copolymers that are not completely end-capped, but that have some free hydroxy ends from the comonomer unit. Typical end groups, in either case, are acetate and methoxy.

### B. EMI Filler

As indicated above, an EMI filler is also distributed within the polymer matrix. The EMI filler may include an electrically conductive material that can provide the desired degree of electromagnetic interference shielding. In certain embodiments, for instance, the material may contain a metal, such as stainless steel, aluminum, zinc, iron, copper, silver, nickel, gold, chrome, etc., as well alloys or mixtures thereof; carbon (e.g., carbon fibers, carbon particles, such as graphite, carbon nanotubes, carbon black, etc.); and so forth). The EMI filler may also possess a variety of different forms, such as particles (e.g., iron powder), flakes (e.g., aluminum flakes, stainless steel flakes, etc.), or fibers.

In particularly suitable embodiments, the EMI filler contains carbon fibers. Generally speaking, the carbon fibers may exhibit a high intrinsic thermal conductivity, such as about 200 W/m-k or more, in some embodiments about 500 W/m-K or more, in some embodiments from about 600 W/m-K to about 3,000 W/m-K, and in some embodiments, from about 800 W/m-K to about 1,500 W/m-K, as well as a low intrinsic electrical resistivity (single filament) of less than about 20 µohm-m, in some embodiments less than about 10 µoh-m, in some embodiments from about 0.05 to about 5 µohm-m, and in some embodiments, from about 0.1 to about 2 µohm-m.

In addition to exhibiting a high degree of intrinsic thermal conductivity and low volume resistivity, such fibers also generally have a high degree of tensile strength relative to their mass. For example, the tensile strength of the fibers is typically from about 500 to about 10,000 MPa, in some embodiments from about 600 MPa to about 4,000 MPa, and in some embodiments, from about 800 MPa to about 2,000 MPa, such as determined in accordance with ASTM D4018-17. The fibers may have an average diameter of from about 1 to about 200 micrometers, in some embodiments from about 1 to about 150 micrometers, in some embodiments from about 3 to about 100 micrometers, and in some embodiments, from about 5 to about 50 micrometers. The fibers may be continuous filaments, chopped, or milled. In certain embodiments, for instance, the fibers may be chopped fibers having a volume average length of the fibers may likewise range from about 0.1 to about 15 millimeters, in some embodiments from about 0.5 to about 12 millimeters, and in some embodiments, from about 1 to about 10 millimeters.

The nature of the carbon fibers may vary, such as carbon fibers obtained from cellulose, lignin, polyacrylonitrile (PAN) and pitch. Pitch-based and PAN-based carbon fibers are particularly suitable for use in the polymer composition. In some embodiments, the carbon fibers are not coated by a metal. Further, in some embodiments, the carbon fibers do not contain carbon nanotubes.

In some embodiments, the carbon fibers include recycled carbon fibers. The recycled carbon fibers may be obtained through various methods known in the art. For example, in some embodiments, carbon fibers which have been formed into a carbon fiber fabric, but which have not been impregnated by a polymer, may be broken down into individual carbon fibers, especially short carbon fibers. An example of a process for recycling carbon fibers into short carbon fiber lengths is disclosed by German Patent Application DE 102009023529, which is incorporated herein by reference.

In other embodiments, the recycled carbon fibers are obtained from carbon fiber-reinforced polymers (CFRPs). One CFRP recycling technique involves subjecting waste CFRP to pyrolysis. This technique utilizes high temperatures to decompose polymeric matrix while attempting to leave the reinforcing fibers intact. Another type of CFRP recycling technique uses chemical agents to chemically react with, degrade, and break down the polymeric matrix (sometimes referred to as depolymerization) to degradation products that may be separated from the carbon fibers, such as by dissolution of the degradation products into a solvent.

A particularly suitable process includes first treating a fiber-reinforced composite with a normally-liquid solvent (e.g., methylene chloride) to prepare a first treated solid residue comprising the reinforcing fibers. The first treatment includes contacting the fiber-reinforced composite with the solvent and dissolving a majority of the matrix into the solvent. After the first treatment, a second treatment of at least a portion of the first treated solid residue comprising the reinforcing fibers with a normally-gaseous material (e.g., carbon dioxide) is preformed to prepare a second treated solid residue. The second treatment includes contacting at least a portion of the first treated solid residue with the normally-gaseous material under conditions of temperature and pressure at which the normally-gaseous material is in a form of a liquid or supercritical fluid. The second treatment may be particularly beneficial for removing residual solvent from the first treated solid residue and may also beneficially remove some additional residual matrix material.

The first treatment may be conducted at any convenient temperature (e.g., temperature of the solvent), but is typically conducted at a temperature that is lower than a normal boiling point of the solvent and is conveniently conducted at ambient temperature. The dissolving may be conducted under an elevated pressure but is often conducted at ambient pressure (approximately one bar). The solvent may include any one or any combination of two or more of the following, with or without other additional components: methylene chloride, methoxy-nonafluorobutane, 2-methyltetrahydrofuran, tetrahydrofuran, tetrachloroethylene, n-propyl bromide, dimethyl sulfoxide, polyolester oil, esters, ethers, acetates, acids, alkalis, amines, ketones, glycol ethers, glycol ether esters, ether esters, ester-alcohols, alcohols, halogenated hydrocarbons, paraffinic hydrocarbons, aliphatic hydrocarbons, aromatic hydrocarbons, and combinations thereof. Methylene chloride is preferred. The normally-gaseous material may include any one or any combination of two or more of the following, with or without the presence of any other component or components: carbon dioxide, 1,1,1,2-tetrafluoroethane, difluoromethane, pentafluoroethane, and combinations thereof. In preferred implementations, the normally-gaseous material is chemically nonreactive, and even more preferably is chemically inert, with respect to the reinforcing fibers. Carbon dioxide is preferred.

The pressure during the second treatment may be within a range of 3 MPa to 69 MPa, such as from about 7 MPa to about 10 MPa. The temperature during second treatment may be within a range from about 0° C. to about 175° C., such as from about 20° C. to about 40° C. A supercritical fluid refers to a fluid at a temperature and pressure above the critical temperature and critical pressure for the material, for example at a temperature above 31.1° C. and a pressure above 72.9 atmospheres (7.39 MPa) in the case of carbon dioxide as the normally-gaseous material. After the second treatment, the vessel can be rapidly depressurized to ambient pressure, which can cause the normally-gaseous material to solidify due to gas expansion cooling. The solidified material can then be sublimated by rinsing with hot water.

The above process is capable of producing recycled carbon fibers which have mechanical properties similar to virgin carbon fibers. U.S. Pat. Nos. 10,487,191; 10,610,911; and 10,829,611, which are incorporated herein by reference, describe carbon fiber recycling processes which are suitable for producing recycled carbon fiber which may be used in the present composition.

It was surprisingly found that the use of recycled carbon fibers, particularly those obtained using the methods described above, leads to increased absorbency of electromagnetic waves compared to virgin carbon fibers. Without intending to be bound by theory, it is believed that the recycled fibers may be better dispersed throughout the matrix in a way that enhances absorbency.

The EMI filler is typically present in an amount of from about 1 wt.% to about 80 wt.%, in some embodiments from about 2 wt.% to about 75 wt.%, in some embodiments from about 5 wt.% to about 70 wt.%, in some embodiments from about 6 wt.% to about 60 wt.%, in some embodiments from about 10 wt.% to about 50 wt.% of the composition, in some embodiments from about 20 wt.% to about 47 wt.%, in some embodiments from about 30 wt.% to about 45 wt.%, and in some embodiments, from about 35 wt.% to about 43 wt.%. The polymer matrix may likewise be present in an amount of from about 20 wt.% to about 99 wt.%, in some embodiments from about 25 wt.% to about 98 wt.%, in some embodiments from about 30 wt.% to about 95 wt.%, in some embodiments from about 40 wt.% to about 94 wt.%, and in some embodiments, from about 50 wt.% to about 90 wt.% of the composition. Of course, the exact amount of the EMI filler will generally depend on the thermoplastic polymer(s), as well as the nature of other components in the composition.

### C. Other Components

In addition to the components noted above, the polymer matrix may also contain a variety of other components. Examples of such optional components may include, for instance, thermally conductive fillers, reinforcing fibers, impact modifiers, compatibilizers, particulate fillers (e.g., talc, mica, etc.), stabilizers (e.g., antioxidants, UV stabilizers, etc.), flame retardants, lubricants, colorants, flow modifiers, pigments, and other materials added to enhance properties and processability.

In some embodiments, the polymer composition of the present invention is capable of achieving a high degree of thermal conductivity without the need for thermally conductive fillers. In this regard, the polymer composition may be generally free of thermally conductive fillers added in addition to the EMI filler. Nevertheless, in certain instances, thermally conductive fillers may be employed. When employed, thermally conductive filler(s) typically constitute no more than about 20 wt.% of the composition, in some embodiments no more than about 10 wt.% of the composition, and in some embodiments, from about 0.01 wt.% to about 5 wt.% the composition. Such thermally conductive fillers generally have a high intrinsic thermal conductivity, such as about 50 W/m-K or more, in some embodiments about 100 W/m-K or more, and in some embodiments, about 150 W/m-K or more. Examples of such materials may include, for instance, boron nitride (BN), aluminum nitride (AIN), magnesium silicon nitride (MgSiN₂), graphite (e.g., expanded graphite), silicon carbide (SiC), carbon nanotubes, carbon black, metal oxides (e.g., zinc oxide, magnesium oxide, beryllium oxide, zirconium oxide, yttrium oxide, etc.), metallic powders (e.g., aluminum, copper, bronze, brass, etc.), etc., as well as combinations thereof. The thermally conductive filler may be provided in various forms, such as particulate materials, fibers, etc. For instance, particulate materials may be employed that have an average size (e.g., diameter or length) in the range of about 1 to about 100 micrometers, in some embodiments from about 2 to about 80 micrometers, and in some embodiments, from about 5 to about 60 micrometers, such as determined using laser diffraction techniques in accordance with ISO 13320:2009 (e.g., with a Horiba LA-960 particle size distribution analyzer).

The polymer composition of the present invention is also capable of achieving a high degree of mechanical strength without the need for additional reinforcements (e.g., reinforcing fibers). In this regard, the polymer composition may be generally free of additional reinforcing fibers. Nevertheless, in certain instances, additional reinforcing fibers may still be employed, albeit typically in a relatively low amount. For example, when employed, additional reinforcing fibers typically constitute no more than about 20 wt.% of the composition, in some embodiments no more than about 10 wt.% of the composition, and in some embodiments, from about 0.01 wt.% to about 5 wt.% the composition. Such reinforcing fibers may be formed from materials that are also generally insulative in nature, such as glass, ceramics (e.g., alumina or silica), aramids (e.g., Kevlar®), polyolefins, polyesters, etc., as well as mixtures thereof. Glass fibers are particularly suitable, such as E-glass, A-glass, C-glass, D-glass, AR-glass, R-glass, S1-glass, S2-glass, etc., and mixtures thereof. The reinforcing fibers may be in the form of randomly distributed fibers, such as when such fibers are melt blended with the high performance polymer(s) during the formation of the polymer matrix. Regardless, the volume average length of the reinforcing fibers may be from about 1 to about 400 micrometers, in some embodiments from about 50 to about 400 micrometers, in some embodiments from about 80 to about 250 micrometers, in some embodiments from about 100 to about 200 micrometers, and in some embodiments, from about 110 to about 180 micrometers. The fibers may also have an average diameter of about 10 to about 35 micrometers, and in some embodiments, from about 15 to about 30 micrometers.

If desired, the EMI filler and other optional components as described below (e.g., thermally conductive fillers, flame retardants, stabilizers, reinforcing fibers, pigments, lubricants, etc.) may be melt blended together to form the polymer matrix. The raw materials may be supplied either simultaneously or in sequence to a melt-blending device that dispersively blends the materials. Batch and/or continuous melt blending techniques may be employed. For example, a mixer/kneader, Banbury mixer, Farrel continuous mixer, single-screw extruder, twin-screw extruder, roll mill, etc., may be utilized to blend the materials. One particularly suitable melt-blending device is a co-rotating, twin-screw extruder (e.g., ZSK-30 twin-screw extruder available from Werner & Pfleiderer Corporation of Ramsey, N.J.). Such extruders may include feeding and venting ports and provide high intensity distributive and dispersive mixing. In certain other embodiments, however, the EMI filler and optional other components may be combined with the polymer matrix using other techniques.

### II. Electronic Module

As indicated above, the polymer composition may be employed in an electronic module, which may contain a housing, at least one electronic component (e.g., antenna element) mounted in the housing, and an electromagnetic interference (EMI) shield mounted over a first side of the antenna element. In some embodiments, the EMI shield may be formed from the polymer composition. The EMI shield may be transparent and/or may contain at least one aperture configured to allow the passage of radio waves to and from the at least one antenna element. When employed in a radar module, for example, the polymer composition is particularly suitable use in the EMI shield because it can possess both EMI shielding properties and electromagnetic absorbency properties, which allow it to dampen the noise of the radio signals reflected within the radar module. However, it should be understood that, while the polymer composition is particularly suitable to forming the EMI shield, it can also be used to form other parts of the radar module. For example, regardless of the particular configuration of the module, the polymer composition of the present invention may be used to form all or a portion of the housing, including sidewall areas that form part of the housing. Notably, one benefit of the present invention is that conventional EMI metal shields (e.g., aluminum plates) and/or heat sinks can be eliminated from the module design, thereby reducing the weight and overall cost of the module. Nevertheless, in certain other embodiments, such additional shields and/or heat sinks may be employed. For example, the module may contain a metal component (e.g., aluminum plate) in some cases.

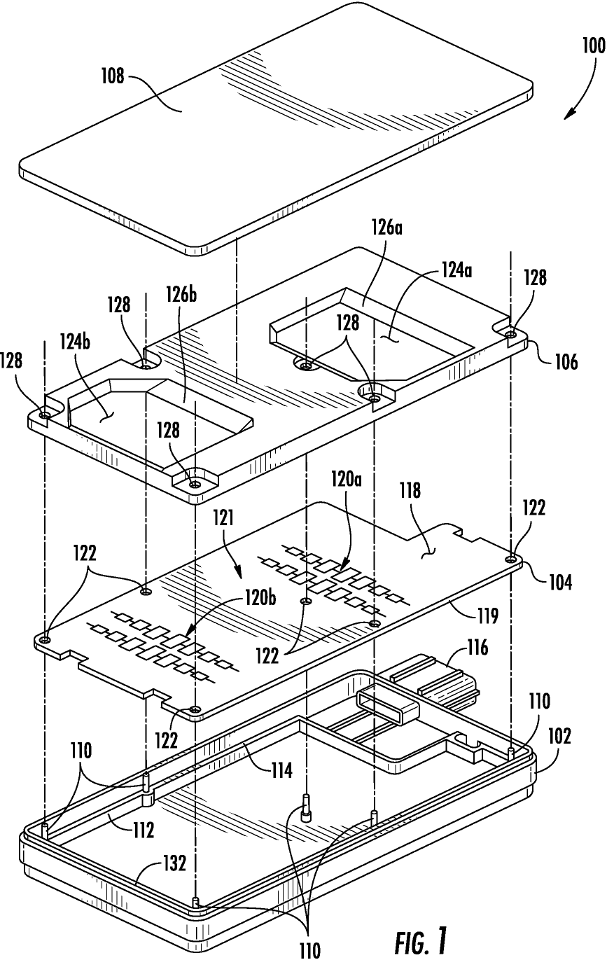

Referring to FIG. 1, one embodiment of a radar module 100 is shown that includes a housing or base 102 in which components of the module 100 are mounted. The module 100 may include a printed circuit board (PCB) 104, an EMI shield 106, and a radome or cover 108 disposed in a stacked configuration and assembled together. The housing 102 can be made of plastic, optionally of the polymer composition described herein, and can be formed by injection molding. The housing 102 can be formed integrally with a shroud 116 for an electrical connector such that shielded electrical connections can be made to the module 100. The use of plastic material for the housing 102 may facilitate welding of the module radome or cover 108 to the housing 102 to ensure a hermetic seal. However, other methods known in the art may also be used to attach the radome to the housing. For the purpose of EMI shielding, the inner surface of the housing 102 can be conductive. To that end, the plastic material of housing 102 can be conductive plastic material. Alternatively, or additionally, a conductive plating or paint can be applied to the inside of housing 102. As another alternative, a metal plate (not shown) may be secured within the inside of the housing. The housing 102 can also include integral heat stake posts 110 used to align PCB 104 via holes 122 and to align the EMI shield 106 via holes 128 and to hold the housing 102, PCB 104 and EMI shield 106 together. After a heat staking operation is performed on heat stake posts 110, a bottom surface 119 of the PCB 104 is held tightly and permanently against conductive top surface 114 of PCB mounting shelf 112 integrally formed in housing 102. Similarly, the EMI shield 106 is held tightly and permanently against a top surface 118 of PCB 104. The radome 108 can be attached to housing 102 via a mating of a groove within the radome 108 with a raised boss 132 on the housing 102.

Antenna elements, such as elements 120a and 120b, may be formed on a top surface 118 of PCB 104 and can also be EMI shielded according to exemplary embodiments. When the EMI shield 106 is assembled over top surface 118 of PCB 104, the apertures 124a and 124b may be disposed to surround and, therefore, expose, the antenna elements 120a and 120b. The portions of the bottom surface of the EMI shield 106 located around the perimeters of apertures 124a and 124b can be held tightly against conductive traces on the PCB 104, such that the apertures 124a and 124b define cavities electrically sealed to the PCB 104 above the antenna elements 120a and 120b, respectively.

Although by no means required, the antenna elements may be configured to receive and/or transmit 5G radiofrequency signals. As used herein, “5G” generally refers to high speed data communication over radio frequency signals. 5G networks and systems are capable of communicating data at much faster rates than previous generations of data communication standards (e.g., “4G, “LTE”). For example, as used herein, “5G frequencies” can refer to frequencies that are 1.5 GHz or more, in some embodiments about 2.0 GHz or more, in some embodiments about 2.5 GHz or higher, in some embodiments about 3.0 GHz or higher, in some embodiments from about 3 GHz to about 300 GHz, or higher, in some embodiments from about 4 GHz to about 80 GHz, in some embodiments from about 5 GHz to about 80 GHz, in some embodiments from about 20 GHz to about 80 GHz, and in some embodiments from about 28 GHz to about 60 GHz. Various standards and specifications have been released quantifying the requirements of 5G communications. As one example, the International Telecommunications Union (ITU) released the International Mobile Telecommunications-2020 (“IMT-2020”) standard in 2015. The IMT-2020 standard specifies various data transmission criteria (e.g., downlink and uplink data rate, latency, etc.) for 5G. The IMT-2020 Standard defines uplink and downlink peak data rates as the minimum data rates for uploading and downloading data that a 5G system must support. The IMT-2020 standard sets the downlink peak data rate requirement as 20 Gbit/s and the uplink peak data rate as 10 Gbit/s. As another example, 3^{rd} Generation Partnership Project (3GPP) recently released new standards for 5G, referred to as “5G NR.” 3GPP published “Release 15” in 2018 defining “Phase 1” for standardization of 5G NR. 3GPP defines 5G frequency bands generally as “Frequency Range 1” (FR1) including sub-6GHz frequencies and “Frequency Range 2” (FR2) as frequency bands ranging from 20-60 GHz. Antenna modules described herein can satisfy or qualify as “5G” under standards released by 3GPP, such as Release 15 (2018), and/or the IMT-2020 Standard.

To achieve high speed data communication at high frequencies, antenna elements and arrays may employ small feature sizes/spacing (e.g., fine pitch technology) that can improve antenna performance. For example, the feature size (spacing between antenna elements, width of antenna elements) etc. is generally dependent on the wavelength (“λ”) of the desired transmission and/or reception radio frequency propagating through the substrate dielectric on which the antenna element is formed (e.g., nλ/4 where n is an integer). Further, beamforming and/or beam steering can be employed to facilitate receiving and transmitting across multiple frequency ranges or channels (e.g., multiple-in-multiple-out (MIMO), massive MIMO). The high frequency 5G antenna elements can have a variety of configurations. For example, the 5G antenna elements can be or include co-planar waveguide elements, patch arrays (e.g., mesh-grid patch arrays), other suitable 5G antenna configurations. The antenna elements can be configured to provide MIMO, massive MIMO functionality, beam steering, and the like. As used herein “massive” MIMO functionality generally refers to providing a large number transmission and receiving channels with an antenna array, for example 8 transmission (Tx) and 8 receive (Rx) channels (abbreviated as 8×8). Massive MIMO functionality may be provided with 8×8, 12×12, 16×16, 32×32, 64×64, or greater.

The antenna elements can have a variety of configurations and arrangements and can be fabricated using a variety of manufacturing techniques. As one example, the antenna elements and/or associated elements (e.g., ground elements, feed lines, etc.) can employ fine pitch technology. Fine pitch technology generally refers to small or fine spacing between their components or leads. For example, feature size/dimensions and/or spacing between antenna elements (or between an antenna element and a ground plane) can be about 5,000 micrometers or less, in some embodiments about 3,000 micrometers or less, in some embodiments 1,500 micrometers or less, in some embodiments 750 micrometers or less (e.g., center-to-center spacing of 1.5 mm or less), 650 micrometers or less, in some embodiments 550 micrometers or less, in some embodiments 450 micrometers or less, in some embodiments 350 micrometers or less, in some embodiments 250 micrometers or less, in some embodiments 150 micrometers or less, in some embodiments 100 micrometers or less, and in some embodiments 50 micrometers or less. However, it should be understood that feature sizes and/or spacings that are smaller and/or larger may be employed within the scope of this disclosure. As a result of such small feature dimensions, antenna modules can be achieved with a large number of antenna elements in a small footprint. For example, an antenna array can have an average antenna element concentration of greater than 10 antenna elements per square centimeter, in some embodiments greater than 50 antenna elements per square centimeter, in some embodiments greater than 200 antenna elements per square centimeter, in some embodiments greater than 1,000 antenna elements per square centimeter, in some embodiments greater than 3,000 antenna elements per square centimeter, and in some embodiments greater than about 5,000 antenna elements per square centimeter. Such compact arrangement of antenna elements can provide a greater number of channels for MIMO functionality per unit area of the antenna area. For example, the number of channels can correspond with (e.g., be equal to or proportional with) the number of antenna elements.

Referring again to FIG. 1, the EMI shielding performance may be enhanced by sidewalls 126a, 126b of apertures 124a, 124b, respectively, in the EMI shield 106. For example, the sidewalls 126a and 126b can be formed at a non-perpendicular slope with respect to the top surface of EMI shield 106. That is, the sidewalls 126a, 126b can be formed at some predetermined acute angle θ with respect to the plane of the top surface of EMI shield 106. It is noted that the reference numeral 126a is used to identify generally any of the sidewalls of aperture 124a, and the reference numeral 126b is used to identify generally any of the sidewalls of aperture 124b. Each of the sidewalls can be formed at a different angle θ, or they can be formed at the same angle θ. According to exemplary embodiments, the angles θ determine the shapes of the shielding cavities above antenna patch patterns 120a and 120b on PCB 104. The angles θ are selected such that the cavities provide shielding characteristics according to operational parameters and characteristics of module 100 in a present desired application. Such operational parameters and characteristics can include, for example, frequency and/or power level target radiation for EMI shielding. In some exemplary embodiments, the angles θ can be selected to maximize the size of apertures 124a, 124b.

Regardless of its particular configuration, an electronic module containing the polymer composition of the present invention may be employed in a wide variety of different application. For example, the electronic module may be employed in an automotive vehicle (e.g., electric vehicle). When used in automotive applications, for instance, the electronic module may be used to sense the positioning of the vehicle relative to one or more three-dimensional objects. Short range automotive radar, for example, can be used for parking assist, blind spot detection, and collision avoidance applications, while long range automotive radar, can be used for dynamic cruise control and cross traffic alert applications.

The polymer composition may also be employed in other types of products. For example, in some embodiments, the polymer composition may be provided as integral part of an entire article or structure used in stealth applications. In other embodiments, a composite structure can have a surface “skin” that incorporates the composition to absorb radar. In other embodiments, the composition material can be applied as a coating or paneling on an already existing surface of another composite or other article. In some embodiments, the composition can be used in a structural component of a transport vessel or projectile for use in stealth applications. The component can be optionally equipped with a mechanism to adjust its angle with respect to an impinging angle of incidence of a radar transmitting source to maximize radar absorption. For example, the energy of the absorbed radar signal can be used to convert to an electrical signal which is integrated with a computer system to alter the orientation of the component to maximize radar absorption. This can provide a means of optimizing against detection from multiple radar sources from previously unknown directions of impingement. In some embodiments, for example, the transport vessel can take the form of a boat, a plane, or a ground vehicle. In other embodiments, the composition can also be used to absorb radar in detector applications, where a reflected radar signal requires efficient capture.

The present invention may be better understood with reference to the following examples.

### Test Methods

Thermal Conductivity: In-plane and through-plane thermal conductivity values are determined in accordance with ASTM E1461-13.

Electromagnetic Interference (“EMI”) Shielding: EMI shielding effectiveness may be determined in accordance with ASTM D4935-18 at frequency ranges ranging from 200 MHz to 18 GHz (e.g., 5 GHz). The thickness of the parts tested may vary, such as 1 millimeter, 1.6 millimeters, or 3.2 millimeters. The test may be performed using an EM-2107A test fixture for low frequencies such as 30 MHz to 1.5 GHz and an EM-2108 standard test fixture for higher frequencies such as from 1.5 GHz to 10 GHz. These text fixtures are enlarged sections of coaxial transmission lines and are available from various manufacturers, such as Electro-Metrics. EMI shielding effectiveness may also be measured according to IEEE std. 299 at frequencies from 1 GHz to 20 GHz. The measured data relates to the shielding effectiveness due to a plane wave (far field EM wave) from which near field values for magnetic and electric fields may be inferred.

Electromagnetic Wave Absorbency: EM absorbency may be determined according to IEEE std. 299. Through the vector network analyzer (VNA), s coefficients can be measured. The absorption amount can then be calculated using the following equation:

$$\text{EM} \text{absorbed} = 1 - {10}^{\left(\text{S21} / 10\right)} - {10}^{\left(\text{S11} / 10\right)}$$

where S21 and S11 are the S coefficients output by the vector network analyzer.

Tensile Modulus, Tensile Stress, and Tensile Elongation at Break: Tensile properties may be tested according to ISO 527-1 :2019 (technically equivalent to ASTM D638-14). Modulus and strength measurements may be made on a dogbone-shaped test strip sample having a length of 170/190 mm, thickness of 4 mm, and width of 10 mm. The testing temperature may be -30° C., 23° C., or 80° C. and the testing speeds may be 1 or 5 mm/min.

Flexural Modulus, Flexural Elongation at Break, and Flexural Stress: Flexural properties may be tested according to ISO 178:2019 (technically equivalent to ASTM D790-17). This test may be performed on a 64 mm support span. Tests may be run on the center portions of uncut ISO 3167 multi-purpose bars. The testing temperature may be -30° C., 23° C., or 80° C. and the testing speed may be 2 mm/min.

Charpy Impact Strength: Charpy properties may be tested according to ISO 179-1:2010) (technically equivalent to ASTM D6110). This test may be run using a Type 1 specimen size (length of 80 mm, width of 10 mm, and thickness of 4 mm). Specimens may be cut from the center of a multi-purpose bar using a single tooth milling machine. The testing temperature may be -30° C., 23° C., or 80° C.

Deflection Temperature Under Load (“DTUL”): The deflection under load temperature may be determined in accordance with ISO 75-2:2013 (technically equivalent to ASTM D648-07). More particularly, a test strip sample having a length of 80 mm, width of 10 mm, and thickness of 4 mm may be subjected to an edgewise three-point bending test in which the specified load (maximum outer fibers stress) was 1.8 Megapascals. The specimen may be lowered into a silicone oil bath where the temperature is raised at 2° C. per minute until it deflects 0.25 mm (0.32 mm for ISO Test No. 75-2:2013).

### Example 1

Sample 1 is a polymer composition that contains 59.3 wt.% of nylon 66, 40 wt.% recycled carbon fibers, 0.4 wt.% of antioxidant, and 0.3 wt.% of lubricant. The composition is formed by melt-processing the components in an extruder.

Sample 1 was tested for mechanical properties, thermal properties, and electrical properties as described herein. The results are set forth below in Tables 1-6.

TABLE 1

Mechanical and Thermal Properties

| Sample | Tensile Strength (MPa) | Tensile Modulus (MPa) | Tensile Elongation (%) | Flex Strength (MPa) | Flex Modulus (MPa) | Notched Charpy (kJ/m²) | DTUL (°C) @1.8 MPa | Thermal Conductivity (in-plane, flow direction) (W/mK) | Thermal Conductivity (thru-plane) (W/mK) |
|---|---|---|---|---|---|---|---|---|---|
| 1 | 217 | 26,600 | 1.1 | 304 | 26,100 | 6.7 | 255 | 2.44 | 0.77 |

TABLE 2

Electrical Properties (2-16 GHz, 3.2 mm)

| | EMI Shielding Effectiveness (SE) at 3.2 mm thickness (IEEE std. 299) [dB] | | | | | | | | Average EMI Shielding Effectiveness (SE) at 3.2 mm thickness [dB] | Average EMI Absorbency at 3.2 mm thickness |
|---|---|---|---|---|---|---|---|---|---|---|
| Sample | 2 GHz | 4 GHz | 6 GHz | 8 GHz | 10 GHz | 12 GHz | 14 GHz | 16 GHz | 2 GHz-16 GHz | 2 GHz-18 GHz |
| 1 | 77.4 | 54.8 | 68.0 | 62.4 | 63.9 | 72.3 | 67.5 | 68.4 | 66.8 | 35% |

Shielding Effectiveness (200 – 1,500 Mhz, 3.2 mm)
EMI Shielding Effectiveness (SE) at 3.2 mm thickness (ASTMD 4935 with EM2107A fixture) [db]

| Sample | 200 MHz | 600 MHz | 1000 MHz | 1500 MHz |
|---|---|---|---|---|
| 1 | 58.25 | 67.52 | 64.05 | 67.47 |

TABLE 4

Shielding Effectiveness (1.5-9 GHz, 1.6 mm)
EMI Shielding Effectiveness (SE) at 1.6 mm thickness (ASTMD 4935 with EM2108 fixture)

| Sample | 1.5 GHz | 2 GHz | 3 GHz | 4 GHz | 5 GHz | 6 GHz | 7 GHz | 8 GHz | 9 GHz |
|---|---|---|---|---|---|---|---|---|---|
| 1 | 47.9 | 50.5 | 51.1 | 46.9 | 52.3 | 53.4 | 56.3 | 54.7 | 47.4 |

TABLE 5

Shielding Effectiveness (2-16 GHz, 1.6 mm)
EMI Shielding Effectiveness (SE) at 1.6 mm thickness (IEEE std. 299)

| Sample | 2 GHz | 4 GHz | 6 GHz | 8 GHz | 10 GHz | 12 GHz | 14 GHz | 16 GHz |
|---|---|---|---|---|---|---|---|---|
| 1 | 61.0 | 37.5 | 60.6 | 55.6 | 62.4 | 63.8 | 67.2 | 70.0 |

TABLE 6

Electrical Properties (30 MHz - 20 GHz)

| Method | Frequency Range | Sample thickness (mm) | Average EMI shielding (dB) | Average EM absorption (%) |
|---|---|---|---|---|
| ASTMD 4935 with EM2107A fixture | 30 MHz - 1.5 GHz | 3.2 | 64.3 | 27% |
| ASTMD 4935 with EM2108 fixture | 1.5 GHz - 10 GHz | 1.6 | 51.2 | 32% |
| IEEE std. 299 Antenna test | 1 GHz-20 GHz | 1.6 | 59.7 | - |
| IEEE std. 299 Antenna test | 1 GHz-20 GHz | 3.2 | 66.8 | - |

### Example 2

Sample 2 is a polymer composition that contains 60 wt.% polyphenylene sulfide and 40 wt.% recycled carbon fibers. The composition is formed by melt-processing the components in an extruder.

Sample 2 was tested for shielding effectiveness as described herein. The results are set forth below in Table 7.

TABLE 7

Shielding Effectiveness (2-16 GHz, 1.6 mm)
EMI Shielding Effectiveness (SE) at 1.6 mm thickness (IEEE std. 299)

| Sample | 2 GHz | 4 GHz | 6 GHz | 8 GHz | 10 GHz | 12 GHz | 14 GHz | 16 GHz |
|---|---|---|---|---|---|---|---|---|
| 1 | 72.8 | 54.2 | 63.2 | 58.7 | 62.3 | 69.3 | 67.6 | 78.1 |

These and other modifications and variations of the present invention may be practiced by those of ordinary skill in the art, without departing from the spirit and scope of the present invention. In addition, it should be understood that aspects of the various embodiments may be interchanged both in whole or in part. Furthermore, those of ordinary skill in the art will appreciate that the foregoing description is by way of example only, and is not intended to limit the invention so further described in such appended claims.

What is claimed is:

1. A polymer composition that includes an electromagnetic interference filler distributed within a polymer matrix that contains a thermoplastic polymer, wherein at a thickness of 3.2 millimeters and over a frequency range from 2 GHz to 18 GHz, the composition exhibits an average absorbency of about 25% or greater and an average electromagnetic interference shielding effectiveness of about 40 decibels or more, as determined in accordance with ASTM D4935-18.

2. The polymer composition of claim 1, wherein the polymer composition exhibits an electromagnetic interference shielding effectiveness of about 40 decibels or more at a frequency of 6 GHz and at a thickness of 3.2 millimeters, as determined in accordance with ASTM D4935-18.

3. The polymer composition of claim 1, wherein the polymer composition exhibits an average electromagnetic interference shielding effectiveness of about 50 decibels or more over a frequency range of 200 MHz to 1.5 GHz at a thickness of 3.2 millimeters, as determined in accordance with ASTM D4935-18.

4. The polymer composition of claim 1, wherein the polymer composition exhibits a thermal conductivity of about 1 W/m-K or more as determined in accordance with ASTM E 1461-13.

5. The polymer composition of claim 1, wherein the polymer composition exhibits a Charpy notched impact strength of about 2 kJ/m² or more as determined in accordance with ISO Test No. 179-1:2010 at a temperature of about 23° C.

6. The polymer composition of claim 1, wherein the polymer composition exhibits a tensile strength of about 100 MPa or more as determined in accordance with ISO Test No. 527-1:2019 at a temperature of about 23° C.

7. The polymer composition of claim 1, wherein the polymer composition exhibits a tensile modulus of from about 10,000 MPa to about 40,000 MPa as determined in accordance with ISO Test No. 527-1:2019 at a temperature of about 23° C.

8. The polymer composition of claim 1, wherein the polymer composition exhibits a flexural strength of from about 150 MPa to about 600 MPa as determined in accordance with ISO Test No. 178:2019 at a temperature of about 23° C.

9. The polymer composition of claim 1, wherein the thermoplastic polymer has a deflection temperature under load of about 150° C. or more as determined in accordance with ISO 75-2:2013 at a load of 1.8 MPa.

10. The polymer composition of claim 1, wherein the thermoplastic polymer includes an aliphatic polymer.

11. The polymer composition of claim 10, wherein the aliphatic polymer includes an aliphatic polyamide.

12. The polymer composition of claim 1, wherein the electromagnetic interference filler constitutes from about 1 wt.% to about 80 wt.% of the composition and the polymer matrix constitutes from about 20 wt.% to about 99 wt.% of the composition.

13. The polymer composition of claim 1, wherein the electromagnetic interference filler comprises carbon fibers.

14. The polymer composition of claim 13, wherein the carbon fibers are recycled carbon fibers.

15. The polymer composition of claim 14, wherein the recycled carbon fibers are produced by treating a carbon fiber-reinforced polymer comprising reinforcing carbon fibers in a polymer matrix with methylene chloride to prepare a first treated solid residue comprising the reinforcing carbon fibers and then treating the solid residue with liquid or supercritical carbon dioxide to obtain the recycled carbon fibers.

16. The polymer composition of claim 13, wherein the carbon fibers have an intrinsic thermal conductivity of about 200 W/m-K or more.

17. The polymer composition of claim 13, wherein the carbon fibers have an electrical resistivity of about 20 µohm-m or less.

18. The polymer composition of claim 13, wherein the carbon fibers are derived from polyacrylonitrile.

19. The polymer composition of claim 13, wherein the carbon fibers are derived from pitch.

20. The polymer composition of claim 19, wherein the pitch includes mesophase pitch.

21. The polymer composition of claim 13, wherein the carbon fibers exhibit a tensile strength of from about 500 to about 10,000 MPa as determined in accordance with ASTM D4018-17.

22. The polymer composition of claim 13, wherein the carbon fibers have an average diameter of from about 1 to about 200 micrometers.

23. An electronic module comprising a housing, at least one electronic component mounted in the housing, and a shield mounted over a first side of the electronic component, wherein the shield and/or the housing comprise the polymer composition of claim 1.

24. The electronic module of claim 23, wherein the shield comprises at least one aperture configured to allow the passage of a radiofrequency signal.

25. The electronic module of claim 23, wherein the shield comprises the polymer composition.

26. The electronic module of claim 23, wherein the electronic component includes an antenna element.

27. The electronic module of claim 23, wherein the electronic module is a radar module.

28. The electronic module of claim 27, further comprising a radome mounted over the shield.

29. A radar module comprising a housing, at least one antenna element mounted in the housing, a shield mounted over a first side of the antenna element, and a radome mounted over the shield, wherein the shield comprises a polymer composition that includes recycled carbon fibers distributed within a thermoplastic polymer matrix.

30. The radar module of claim 29, wherein at a thickness of 3.2 millimeters and over a frequency range from 2 GHz to 18 GHz, the polymer composition exhibits an average absorbency of about 25% or greater and an average electromagnetic interference shielding effectiveness of about 40 decibels or more, as determined in accordance with ASTM D4935-18.

31. The radar module of claim 29, wherein the polymer composition exhibits an electromagnetic interference shielding effectiveness of about 40 decibels or more at a frequency of 6 GHz and at a thickness of 3.2 millimeters, as determined in accordance with ASTM D4935-18.

32. The radar module of claim 29, wherein the polymer composition exhibits an average electromagnetic interference shielding effectiveness of about 50 decibels or more over a frequency range of 200 MHz to 1.5 GHz at a thickness of 3.2 millimeters, as determined in accordance with ASTM D4935-18.

33. The radar module of claim 29, wherein the polymer composition exhibits a thermal conductivity of about 1 W/m-K or more as determined in accordance with ASTM E 1461-13.

34. The radar module of claim 29, wherein the thermoplastic polymer has a deflection temperature under load of about 150° C. or more as determined in accordance with ISO 75-2:2013 at a load of 1.8 MPa.

35. The radar module of claim 29, wherein the thermoplastic polymer includes an aliphatic polymer.

36. The radar module of claim 35, wherein the aliphatic polymer includes an aliphatic polyamide.

37. The radar module of claim 29, wherein the electromagnetic interference filler constitutes from about 1 wt.% to about 80 wt.% of the composition and the polymer matrix constitutes from about 20 wt.% to about 99 wt.% of the composition.

38. The radar module of claim 29, wherein the recycled carbon fibers have an intrinsic thermal conductivity of about 200 W/m-K or more.

39. The radar module of claim 29, wherein the recycled carbon fibers have an electrical resistivity of about 20 µohm-m or less.

40. The radar module of claim 29, wherein the recycled carbon fibers are derived from polyacrylonitrile.

41. The radar module of claim 29, wherein the recycled carbon fibers are derived from pitch.

42. The radar module of claim 41, wherein the pitch includes mesophase pitch.

43. The radar module of claim 29, wherein the recycled carbon fibers exhibit a tensile strength of from about 500 to about 10,000 MPa as determined in accordance with ASTM D4018-17.

44. The radar module of claim 29, wherein the recycled carbon fibers have an average diameter of from about 1 to about 200 micrometers.

45. The radar module of claim 29, wherein the recycled carbon fibers are produced by treating a carbon fiber-reinforced polymer comprising reinforcing carbon fibers in a polymer matrix with methylene chloride to prepare a first treated solid residue comprising the reinforcing carbon fibers and then treating the solid residue with liquid or supercritical carbon dioxide to obtain the recycled carbon fibers.
